(19) United States
(12) Patent Application Publication
(10) Pub. No.: US 2004/0188863 A1
(43) Pub. Date: Sep. 30, 2004

(54) Substrate for semiconductor package and method of making same

(76) Inventor: Zhong Cheng Wang, Taichung City (TW)

Correspondence Address: ZHONG CHENG WANG, P.O. Box 63-150, Taichung City, TW

(21) Appl. No.: 10/403,925

(22) Filed: Mar. 24, 2003

(51) Int. Cl. H01L 23/28

(52) U.S. Cl. 257/787

(57) ABSTRACT

The present invention provides a substrate for a semiconductor and the semiconductor package, wherein with the setup that the conductive fingers around the chip of enclosure structure superposes with the electrical connecting element, the distance between the conductive fingers and the chip will be shortened, so as to effectively shorten the wires from the chip to the conductive fingers and reduce the materials and the processing time, in favor of cutting down the cost of production.

### BACKGROUND OF THE INVENTION

1. Field of the Invention

The invention relates to a substrate for semiconductor package and method of making same, more particularly to a constitution of saving wire bonding time and materials.

2. Description for the Prior Art

Science and technology are quickly developing today, and the electronic products are intentionally designed light, thin, small, wide application and low cost, in order to achieve above object the industry are making full effort.

FIG. 5A and 5B, as referred, are the top and cross-sectional views of conventional semiconductor packaging structure, of which including a substrate 3 having first surface 3a and second surface 3b. There are a plurality of conductive balls 5 on the second surface 3b, on the first surface 3a is mounted a chip 2, which is surrounded with first electrical connecting element 7a, second electrical connecting element 7b and third electrical connecting element 7c. Those electrical connecting elements 7a, 7b and 7c are electrically connected to the chip 2 through a plurality of conductive wires 6. The first, second and third electrical connecting elements 7a, 7b and 7c may be the supplies of power, grounding or any other type of electrical connection. And a plurality of conductive fingers 7 are set on the circumferential edges of connecting elements 7a, 7b and 7c, upon which are coated with an insulator 8. The conductive fingers 7 also are electrically connected to chip 2 via a number of conductive wires 6. The encapsulant resin 4 encapsulates chip 2, conductive wires 6, the first, second and third electrical connecting elements 7a, 7b, 7c, and conductive fingers 7. Hereinto, the length of conductive wires 6 from chip 2 to conductive fingers 7 are the longest, as this result more materials are used. Because conductive wire 6 is usually made of expensive pure gold , more conductive wires are used, the cost will be higher and longer processing time required. It is necessary to make improvement because of its quite adverse to fabrication.

In the view of above, the inventor invented the present invention to solve this problem to reduce the length of conducting wires and fabrication cost, which is actually a progressive invention.

### SUMMARY OF THE INVENTION

The present invention provides a substrate for semiconductor package and method of making same, wherein the conductive fingers and electrical connecting element are set with stacking, as this result, the volume of conductive wires and processing time are reduced and electrical performance improved, because of the distance between the conductive fingers and chip are shortened.

### DETAILED DESCRIPTION OF THE PREFERRED EMBODIMENT

The following is a description of the present invention in the respect of technology, means adopted and its function; hereby a preferred embodiment accompanying figures are provided as following:

FIG. 1˜4, as shown, are the illustrated schematically structure of this embodiment, and only for description without restriction to the patent application.

Firstly, refer to FIG. 1 including:

A substrate 30 has a first surface 31 and a second surface 32 on which a plurality of conductive balls 50 are mounted;

A chip 20 is mounted on the first surface 31 of the substrate 30;

A plurality of conductive fingers 70 and 700 are situated around the chip 20. The said conductive finger 700 is comprised of a plurality of submembers 70A, 70B and 70C. And the said submember 70B may not be involved as requirement, moreover, the conductive finger 700 may comprise only a submember;

The first and third electrical connecting elements 72 and 76 are situated on the conductive fingers 70 and 700 via an insulator 80; a second electrical connecting element 74 is situated on the first electrical element 72 via another insulator 82, wherein, these electrical connecting elements 72, 74 and 76 may also be formed of circuit board having electrical traces (i.e. printed circuit board or the equal);

A plurality of conductive wires 60 are electrically connected the said electrical connecting elements 72, 74, 76, and the conductive fingers 70 and 700 to the chip 20 respectively; in this embodiment, as desired, these said electrical connecting elements 72, 74 and 76 may also be electrically connected to any terminal on the substrate 30 via the conductive wires 60.

An encapsulant resin 40 encapsulates the chip 20, conductive wires 60, the first, second, third electrical connecting elements 72,74, 76, and conductive fingers 70 and 700;

Thereby, the conductive fingers 70 and 700, and electrical connecting elements 72, 74 and 76 are piled together to shorten the distance of conductive wires 60 from chip 20 to conductive fingers 70 and 700, so that less materials are needed and the manufacturing time and cost also reduced.

As shown in FIG. 2, it is the other embodiment of present invention, wherein the chip 20 is situated in the containing space 35 of the substrate 30, and the conductive fingers 70 are set around the containing space 35; the first electrical connecting element 72 and conductive fingers 70 are electrically connected to the chip 20 via conductive wires 60 respectively; the insulator 80 and a plurality of conductive parts 77 are situated between the conductive fingers 70 and the first electrical connecting element 72,wherein the conductive parts 77 may electrically connect the first electrical connecting element 72 to the conductive fingers 70 and the conductive traces 33 of the substrate 30 respectively; a plurality of insulators 85 are coated on the electrical connecting element 72 to prevent from the damage by the short circuit if the conducive wire 60 spaning over the first electrical connecting element 72, it can also protect the first electrical connecting element 72 with the buffer of insulator 85 to reduce impact of stress caused by encapsulant resin 40, especially as marked in the figure, this insulator 85 may press and flatten the conductive fingers 70 by on its side; in addition, the said insulator 85 and the first electrical connecting element 72 may be set simultaneously while fabricating substrate 30, or may be set after the fabrication of substrate 30.

As shown in FIG. 3, it is yet another embodiment of the invention, wherein plurality electronic components 90 are set up on the first, second, third and fourth electrical connecting elements 72, 74, 76 and 78. These electronic components 90 will be made up of resistance, capacitor or any electronic part. Furthermore, the first, second, third and fourth electrical connecting elements 72, 74, 76 and 78 are comprised of recessed portions and protruding portions 72A, 74A, 76A and 78A as required, the length of conductive wires 60 may also be shortened. When the conductive wires 60 are bonding from the chip 20 to the first, second, third and fourth electrical connecting elements 72, 74, 76 and 78, resulting in only a short length of conductive wires 60 needed and reaching the purpose of less material and preferred electrical performance. As the requirement, the fifth electrical connecting element 79 just electrically connects to the chip 20 via a conductive wire 60.

As shown in FIG. 4, it is another embodiment of the invention, wherein the first chip 20 and the second chip 22 are set in containing space 35 of substrate 30, with a structure of the insulator 80 and the conductive fingers 70, the electrical connecting element 72 will be respectively set on the first surface 31 and the second surface 32 of the substrate 30, and by the electrical connection of conductive wires 60 and chips 20 and 22, the performance of the semiconductor package may be improved.

The above is only a preferred embodiment of the invention, which is unable to limit the implementation scope of the invention. So the modification of value or the replacement of equivalent component, or the equal change and decoration according to the claims of the invention is still contained in the scope of the invention.

### BRIEF DESCRIPTION OF THE DRAWINGS

FIG. 1 is a cross-sectional view of the structure embodiment of the invention;

FIG. 2 is a schematic view of conductive parts and insulators;

FIG. 3 is the status of different shapes of electrical connecting elements;

FIG. 4 is a schematic view of electrical connecting elements set on the second surface of the substrate;

FIG. 5A is a top view of conventional semiconductor package structure;

FIG. 5B is a cross-sectional view of conventional semiconductor package structure.

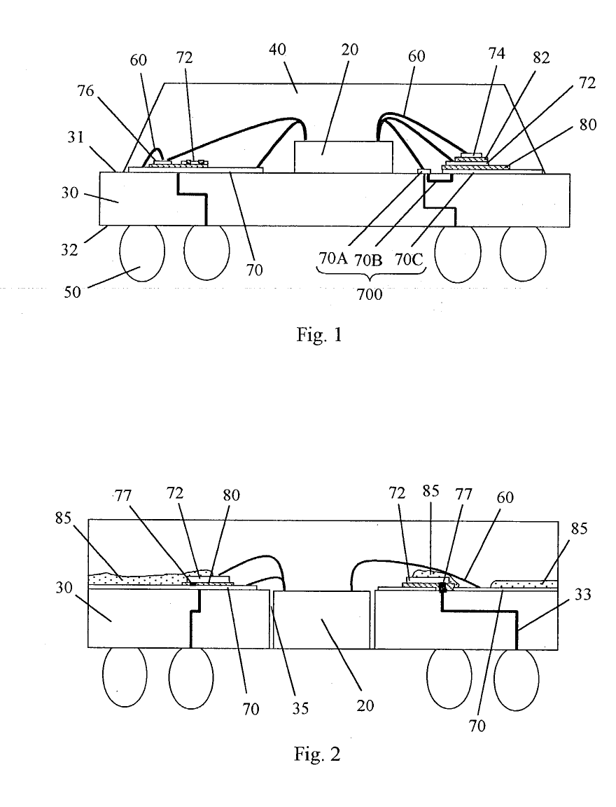

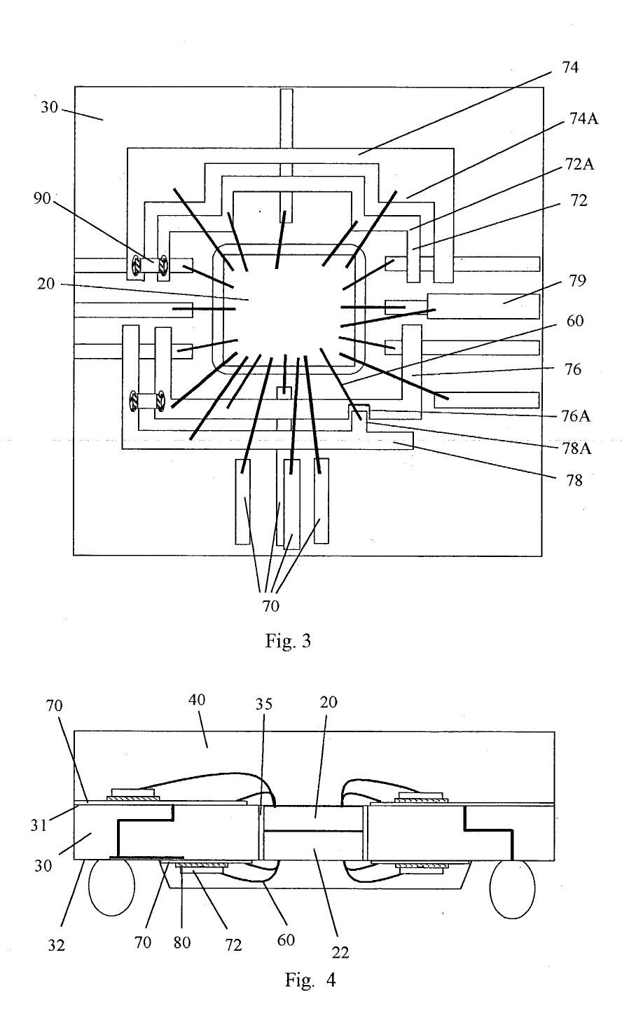

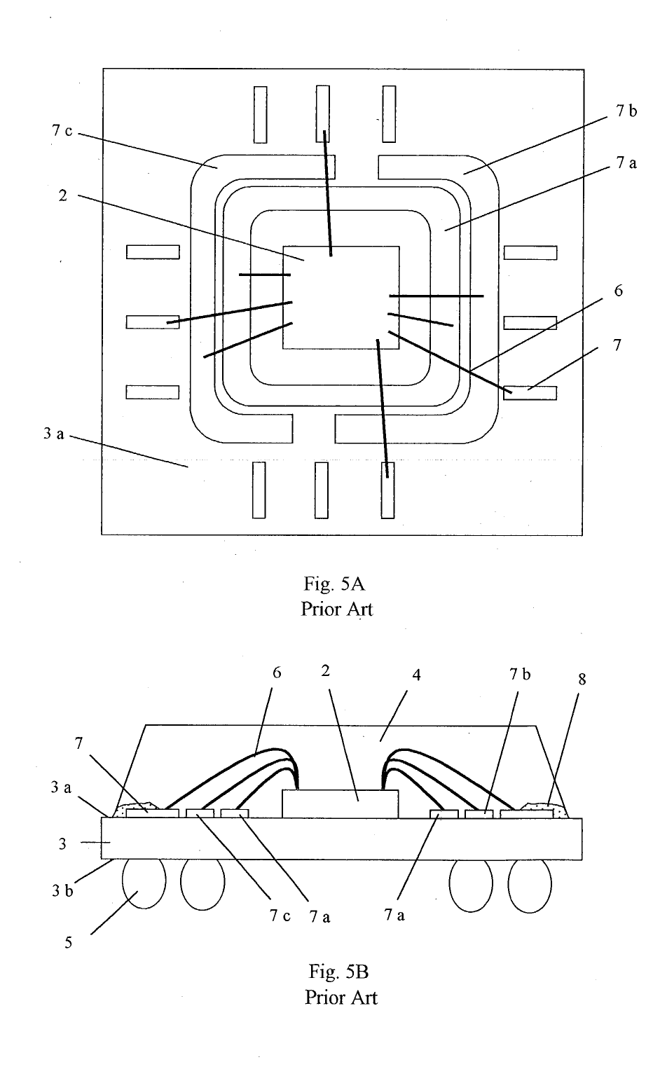

1. (currently amended) A substrate for semiconductor package comprising:
a substrate having at least a first surface and at least a second surface; at least a conductive finger set up on at least a surface of the substrate; and at least an electrical connecting element being set up on the conductive finger by an insulator, hereby it having a feature that the conductive finger and the electrical connecting element form a mutual superposition [[;]], wherein one end of [[the]] said conductive finger stretches out compared with the electrical connecting element and protrudes toward the area where the containing space which area planned to be install installed at least a chip ; and both of the conductive finger and the electrical connecting element leave contact portion for external electrical connection electrically connecting to conductive wire respectively, wherein said electrical connecting element for electrically connecting to at least a chip by a plurality of conductive wires, and said electrical connecting element being selectively serving as a power supply or ground; and said conductive finger for electrically connecting to at least a chip by a conductive wire, wherein said electrical connecting element does not protrude the periphery of said substrate.

2. (currently amended) The substrate for semiconductor package of claim 1, further comprising at least a containing space, wherein the wherein said containing space is an area selected from the group consisting of a planar, a cavity, and a through hole, where being installed at least a chip.

3. (canceled)

4. (canceled)

5. (currently amended) The substrate for semiconductor package of claim 1, [[the ]] wherein said electrical connecting element is employed as a printed circuit board.

6. (currently amended) The substrate for semiconductor package of claim 1, wherein the surface of [[the]] said electrical connecting element being covered with insulator partially.

7. (currently amended) The substrate for semiconductor package of claim 1, wherein [[the]] said electrical connecting element by using a conductive part, said conductive part penetrates goes through the insulator and electrically connects said electrical connecting element to the conductive finger.

8. (currently amended) The substrate for semiconductor package of claim 1, wherein [[the ]] said electrical connecting element by using a conductive part, said conductive part penetrates goes through the insulator and electrically connects said electrical connecting element to the electrical trace of substrate.

9. (currently amended) A semiconductor package comprising:
a substrate having at least a first surface and at least a second surface; at least a conductive finger set up on at least a surface of the substrate; and at least an electrical connecting element being set up on the conductive finger by an insulator, hereby it having a feature that the conductive finger and the electrical connecting element form a mutual superposition [[;]] wherein one end of [[the]] said conductive finger stretches out compared with the electrical connecting element and protrudes toward the area where the containing space which area planned to be install installed at least a chip ;and both of the conductive finger and the electrical connecting element leave contact portion for external electrical connection electrically connecting to conductive wire respectively.
at least a chip being coupled with the substrate; and a plurality of conductive wires electrically connecting the conductive finger and the electrical connecting element respectively to the chip, wherein said electrical connecting element being electrically connected to said chip by a plurality of conductive wires, and the function of said electrical connecting element being selectively serving as a power supply or ground, and said electrical connecting element does not protrude the periphery of said substrate.

10. (currently amended) The semiconductor package of claim 9, wherein the substrate having at least a containing space, wherein [[the]] said containing space is an area selected from the group consisting of a planar area, a cavity, and a through hole, where being installed at least a chip.

11. (canceled)

12. (currently amended) The semiconductor package of claim 9, [[the]] wherein said electrical connecting element is employed as a printed circuit board.

13. The semiconductor package of claim 9, wherein [[the]] said electrical connecting element by using a conductive part, said conductive part penetrates goes through the insulator and electrically connects said electrical connecting element to the conductive finger.

14. (currently amended) The semiconductor package of claim 9, wherein [[the]] said electrical connecting element by using a conductive part, said conductive part penetrates goes through the insulator and electrically connects said electrical connecting element to the electrical trace of substrate.

15. (currently amended) The semiconductor package of claim 9, wherein [[the]] said electrical connecting element electrically connects to the conductive finger by a conductive wire.

16. (currently amended) The semiconductor package of claim 9, further comprising wherein at least an electrical component wherein said electrical component is set up on at least an electrically connects said electrical connecting element.

17. (currently amended) The substrate for semiconductor package of claim 1, wherein [[the]] said electrical connecting element being set up on a plurality of [[the]] said conductive fingers by an insulator.

18. (currently amended) The semiconductor package of claim 9, wherein [[the]] said electrical connecting element being set up on a plurality of [[the]] said conductive fingers by an insulator.

19. (new) The substrate for semiconductor package of claim 1, wherein said electrical connecting element electrically connects to the conductive finger by a conductive wire.

20. (new) The substrate for semiconductor package of claim 1, wherein said electrical connecting element having at least a recessed portion.

21. (new) The substrate for semiconductor package of claim 1, wherein said electrical connecting element having at least a protruding portion.

22. (new) The semiconductor package of claim 9, wherein said electrical connecting element having at least a recessed portion.

23. (new) The semiconductor package of claim 9, wherein said electrical connecting element having at least a protruding portion.
